(19) United States
(12) Patent Application Publication
(10) Pub. No.: US 2021/0159102 A1
(43) Pub. Date: May 27, 2021

(54) THERMAL TREATMENTS USING A PLURALITY OF EMBEDDED RESISTANCE TEMPERATURE DETECTORS (RTDs)

(71) Applicant: Tokyo Electron Limited, Tokyo (JP)

(72) Inventor: Melvin Verbaas, Yamanashi (JP)

(21) Appl. No.: 16/951,093

(22) Filed: Nov. 18, 2020

Related U.S. Application Data
(60) Provisional application No. 62/940,469, filed on Nov. 26, 2019.

(51) Int. Cl. H01L 21/67; H05B 3/28

(52) U.S. Cl. CPC H01L 21/67248; H01L 21/67103; H05B 3/283

(57) ABSTRACT

Bake modules and related heaters for the processing of microelectronic workpieces, such as semiconductor substrates, are disclosed that include a plurality of resistance temperature detectors (RTDs) embedded into the heater to sense temperatures in different zones of the heater. Related methods are also disclosed.

### CROSS REFERENCE TO RELATED PATENTS AND APPLICATIONS

This application claims priority to and the benefit of the filing date of U.S. Non-Provisional Patent Application No. 62/940,469, filed Nov. 26, 2019, which application is incorporated herein by reference in its entirety.

### BACKGROUND

The present disclosure relates to bake plates for thermally treating substrates.

A photolithography process flow may include various semiconductor bake processes including, e.g., a post application bake (PAB), a post exposure bake (PEB) and/or a post development bake (PDB). These bake processes can be used to thermally treat (i.e., heat or bake) one or more liquid solutions, layers, or films applied to or deposited onto a substrate. During these bake processes, solvent-rich, polymer-containing, layers or films are baked at temperatures close to and potentially well above the boiling point of the casting solvent used. The bake process time and temperature are used to drive out solvents and cure or harden the film, thereby defining the characteristics of the film at exposure and post exposure develop where the circuit feature is defined, prior to etching the feature into the substrate.

FIG. 1 (Prior Art) illustrates an exemplary bake module 10, which may be configured to perform a bake process, such as a PAB, PEB, or PDB process. The bake module 10 shown in FIG. 1 (Prior Art) could be a stand-alone bake module or may be incorporated within a substrate processing system that includes various modules for processing semiconductor substrates. As shown in FIG. 1 (Prior Art), bake module 10 may generally include a processing chamber 12 bounded by one or more exterior walls 14, a bake plate (or heater) 16 disposed within the processing chamber 12, and a bake chamber lid 18 forming a portion of the processing chamber 12. The bake module 10 shown in FIG. 1 (Prior Art) also includes at least one horizontal shielding plate 20, one or more interior walls 22 and a supporting plate 24. The horizontal shielding plate 20 and the interior walls 22 are coupled to the exterior wall(s) 14 of the bake module 10, while the supporting plate 24 is coupled between the interior walls 22 to form a mounting region for the bake plate 16. Although not shown in FIG. 1 (Prior Art), bake plate 16 and supporting plate 24 may each include a plurality of through-holes through which lift pins can be inserted and used to lift a substrate (e.g., a semiconductor wafer, W) off, or lower the substrate onto, the upper surface of the bake plate.

When bake module 10 is configured in a wafer transfer mode, the lift pins (not shown) can be pushed up to allow a substrate (or wafer, W) to be transferred into/out of the bake module. As shown in FIG. 1 (Prior Art), a processing arm 26 may be used to transfer a substrate into/out of bake module 10 via an opening 28 formed in at least one of the exterior walls 14. The processing arm 26 may position the substrate onto lift pins, which are then lowered to arrange the substrate on or above the upper surface of the bake plate 16. When retrieving a substrate from bake module 10, the lift pins may be raised so that the processing arm 26 can retrieve the substrate from the bake plate 16 and unload the substrate through opening 28.

When bake module 10 is configured in an operating mode, the lift pins (not shown) can be pulled down to arrange the substrate on the bake plate 16 and begin thermal treatment in the processing chamber 12. During a bake process (such as, e.g., a PAB, PEB, or PDB process), the temperature of bake plate 16 is raised to thermally treat (i.e., heat or bake) the wafer. For example, the temperature of the bake plate 16 may be increased (e.g., to a temperature between about 80° C. and about 250° C.) to thermally treat one or more layers or films that were previously applied or deposited onto the substrate. Typical layers or films include, but are not limited to, topcoat barrier layers (TC), topcoat antireflective layers (TARC), bottom antireflective layers (BARC), imaging layers (PR or photoresist) and sacrificial and barrier layers (hard mask) for etch stopping. During the bake process, gas generated from the surface of the substrate before, during, and/or after the bake process may be exhausted through an exhaust port 30 formed in the bake chamber lid 18, and vented from the processing chamber 12 via exhaust line 32 and exhaust unit 34.

In some cases, the bake plate 16 included within bake module 10 may be formed from a ceramic material having a high thermal conductivity and low coefficient of thermal expansion, such as silicon nitride (Si₃N₄), SiAlON (ceramic materials including silicon (Si), aluminum (Al), oxygen (O), and nitrogen (N)), aluminum nitride (AlN), aluminum oxide (Al₂O₃), boron nitride (BN), or a ceramic material having low electrical conductivity. Aluminum nitride is commonly used to form bake plates used to thermally treat semiconductor substrates, due to its high thermal conductivity (e.g., >130 W/mK), low coefficient of thermal expansion (e.g., 3-6 10⁻⁶/° C.), high maximum temperature (e.g., up to about 1700° C.) and excellent corrosion resistance.

As shown in FIG. 1 (Prior Art), bake module 10 may also include one or more resistive heating elements 36, one or more temperature sensors 38 and a controller 40. The one or more resistive heating elements 36 may be embedded within the bake plate 16 to generate heat, which is used to thermally treat the substrate (or wafer W) mounted on or above an upper surface of the bake plate. The one or more temperature sensors 38 may be embedded within the bake plate 16 to measure the temperature of the bake plate. Controller 40 is coupled to the resistive heating element(s) 36 and the temperature sensor(s) 38 and configured to control the temperature of the bake plate 16 based on the temperature measurement received from the temperature sensor(s). For example, a power source associated with controller 40 may be coupled to supply current to resistive heating element(s) 36. Upon receiving a temperature measurement from temperature sensor(s) 38, controller 40 may maintain or adjust the amount of current supplied to the resistive heating element(s) 36 to maintain or adjust the amount of heat generated thereby.

In some cases, a single resistive heating element 36 formed from a coiled metal wire may be embedded within the bake plate 16, as shown in FIG. 2 (Prior Art). In some cases, the resistive heating element 36 shown in FIG. 2 (Prior Art) may be formed from a metal material having a high melting point and a thermal coefficient of expansion that is greater than or equal to that of the ceramic material used to form the bake plate 16. A metal material with a relatively high melting point is typically required, due to the high sintering temperature (e.g., about 1700° C. for AlN) of the ceramic material used to form the bake plate 16. Selecting a metal material with a thermal coefficient of expansion that is greater than or equal to that of the ceramic material used to form the bake plate 16 prevents microcracks from forming in the bake plate over time with repeated heating/cooling cycles. When bake plate 16 is formed from aluminum nitride (AlN), tungsten, molybdenum and alloys thereof are commonly used to form resistive heating element 36. A nickel alloy and other metal alloys having stability at high temperatures can also be used to implement the resistive heating element 36.

In FIG. 2 (Prior Art), a single temperature sensor 38 is positioned near and/or in direct contact with the resistive heating element 36 to measure the temperature of the resistive heating element. In many cases, temperature sensor 38 may be implemented as a straight metal, type K thermocouple (TC) tube. The thermocouple is typically inserted within a hole formed within the bake plate 16, which is often centered within the bake plate.

Unfortunately, the temperature sensor 38 included within the bake plate 16 shown in FIG. 2 (Prior Art) is undesirable for many reasons. First, a straight metal, type K thermocouple (TC) tube cannot be sintered into a bake plate formed from aluminum nitride (AlN), since the maximum continuous temperature of a type K thermocouple (e.g., about 1100° C.) is much less than the sintering temperature of AlN (e.g., about 1700° C.). Second, since a straight metal TC tube has limited flexibility, it cannot be used to directly measure the temperature in the outer zones of the bake plate 16. Although the outer zone temperature may be approximated (e.g., by applying an offset to the temperature measured by temperature sensor 38), the approximated temperature usually fails to properly control temperatures in the outer zone, often resulting in breakage of the bake plate 16. In addition, because the temperature sensor 38 shown in FIG. 2 (Prior Art) is positioned near and/or in direct contact with the resistive heating element 36, it cannot be used to accurately measure the temperature near the upper surface of the bake plate 16 or closely approximate the temperature of the substrate (or wafer, W) mounted thereon.

In other cases, a plurality of resistive heating elements 36 may be embedded within the bake plate 16 to create a bake plate with multiple heating zones. In the example shown in FIG. 3 (Prior Art), for example, an inner heating element 36a and an outer heating element 36b are embedded within bake plate 16 to create a bake plate with dual heating zones. When bake plate 16 is formed from aluminum nitride (AlN), the inner and outer heating elements 36a/b may be formed from tungsten, molybdenum or an alloy thereof as well as from a nickel alloy or another a metal alloy having stability at high temperatures to enable the heating elements to withstand high AlN sintering temperatures and to prevent microcracks from forming in the bake plate over time. In the example shown in FIG. 3 (Prior Art), the inner and outer heating elements 36a/b are positioned relatively far away from the upper surface of the bake plate 16 to prevent the heating elements from imprinting on the substrate.

In FIG. 3 (Prior Art), a single temperature sensor 38 is positioned near an upper surface of the bake plate 16 to monitor a temperature near the upper surface of the bake plate, and to more closely approximate the temperature of the substrate (or wafer, W) mounted thereon. As with the previous example shown in FIG. 2 (Prior Art), the temperature sensor 38 shown in FIG. 3 (Prior Art) may be implemented as a straight metal, type K thermocouple (TC) tube, which is inserted within a hole formed and centered within the bake plate 16. As such, the temperature sensor 38 shown in FIG. 3 (Prior Art) suffers from many of the same disadvantages as the temperature sensor 38 shown in FIG. 2 (Prior Art). For example, the straight metal, type K TC tube shown in FIG. 3 (Prior Art) cannot be sintered into an AlN bake plate and cannot be used to accurately measure temperatures in the outer zones of the bake plate.

In some cases, the inner and outer heating elements 36a/b shown in FIG. 3 (Prior Art) can be used to estimate and independently control the temperature of the bake plate 16 in the inner and outer heating zones. For example, controller 40 may be configured to measure a resistance of the currents flowing through the inner and outer heating elements 36a/b, and may use a temperature coefficient of resistance (TCR) curve to correlate resistance to temperature of the inner and outer heating elements 36a/b. Once the temperatures of the inner and outer heating elements 36a/b are calculated, the controller 40 may use the calculated temperatures to independently control the temperatures generated within the inner and outer heating zones.

Unfortunately, since the inner and outer heating elements 36a/b shown in FIG. 3 (Prior Art) are positioned relatively far away from the upper surface of the bake plate 16, they cannot be used to accurately monitor the temperature of the substrate (or wafer, W) mounted thereon, since the surface/substrate temperature (e.g., about 580° C., in some cases) is typically much lower than the temperature of the inner and outer heating elements (e.g., about 690° C.). In addition, high temperatures and diffusion may cause the TCR curve to change or drift, thereby reducing the accuracy of the temperatures calculated from the TCR curve.

### SUMMARY

Embodiments are described herein for bake modules and heaters for the processing of microelectronic workpieces, such as semiconductor substrates, where a plurality of resistance temperature detectors (RTDs) are embedded into the heater to sense temperatures in different zones of the heater. Various embodiments can be implemented, and related systems and methods can be utilized as well.

For one embodiment, a bake module is disclosed including a heater configured to thermally treat a substrate mounted on or above an upper surface of the heater and a plurality of resistance temperature detectors (RTDs) embedded within the heater prior to sintering the heater and configured to sense temperatures for different zones of the heater. In further embodiments, the heater includes a bake plate and/or a susceptor cap coupled to the bake plate, and at least one resistive heating element is embedded within the bake plate and configured to generate heat to thermally treat the substrate.

In additional embodiments, the bake plate is formed from a ceramic material having a high thermal conductivity and a low coefficient of thermal expansion. In other further embodiments, the bake plate is formed from silicon nitride (Si₃N₄), SiAlON, aluminum nitride (AlN), aluminum oxide (Al₂O₃), or boron nitride (BN).

In additional embodiments, the at least one resistive heating element and the plurality of RTDs are formed from a metal material having a high melting point and a thermal coefficient of expansion that is greater than or equal to that of a ceramic material used to form the bake plate. In other further embodiments, the at least one resistive heating element and the plurality of RTDs are formed from one or more of tungsten, molybdenum, a tungsten-molybdenum alloy, a nickel alloy, and a metal alloy. In one embodiment, the plurality of RTDs are formed from a metal material having a melting point greater than a sintering temperature of the heater.

In additional embodiments, the at least one resistive heating element includes a first resistive heating element configured to generate heat within an inner heating zone of the heater and a second resistive heating element configured to generate heat within an outer heating zone of the heater.

In additional embodiments, each of the plurality of RTDs is embedded within the bake plate, or within the susceptor cap coupled to the bake plate, and positioned above the at least one resistive heating element near the upper surface of the heater. Further, a first RTD of the plurality of RTDs is further positioned near a lateral center of the bake plate and configured to provide a first output current corresponding to a first temperature that is generated within an inner heating zone of the bake plate near the upper surface of the heater, and a second RTD of the plurality of RTDs is further positioned near an outer edge of the bake plate and configured to provide a second output current corresponding to a second temperature that is generated within an outer heating zone of the bake plate near the upper surface of the heater.

In additional embodiments, the plurality of RTDs comprise a resistive grid of conductors, each of which is configured to provide an electrical resistance between 100 ohms and 1000 ohms.

In additional embodiments, the bake module includes a controller coupled to receive the first output current from the first RTD and the second output current from the second RTD. Further, the controller is configured to monitor the first temperature and the second temperature by determining a first resistance from the first output current, determining a second resistance from the second output current, and using at least one temperature coefficient of resistance (TCR) curve to correlate the first resistance to the first temperature generated within the inner heating zone of the bake plate and to correlate the second resistance to the second temperature generated within the outer heating zone of the bake plate.

In additional embodiments, the bake module includes a controller coupled to receive the first output current from the first RTD and the second output current from the second RTD. Further, the controller is configured to control the first temperature generated within the inner heating zone based on the first output current received from the first RTD and to control the second temperature generated within the outer heating zone of the bake plate based on the second output current received from the second RTD, where the controller is configured to control the second temperature independently of the first temperature.

For one embodiment, a heater configured to thermally treat a substrate mounted on or above an upper surface of the heater is disclosed including a first resistive heating element embedded within the heater to generate heat within a first heating zone of the heater, a second resistive heating element embedded within the heater to generate heat within a second heating zone of the heater, and a plurality of resistance temperature detectors (RTDs) where each RTD is embedded within the heater prior to sintering the heater and positioned above the first resistive heating element and the second resistive heating element near the upper surface of the heater. Further, a first RTD of the plurality of RTDs is positioned within the first heating zone and used to monitor a first temperature that is generated within the first heating zone near the upper surface of the heater, and a second RTD of the plurality of RTDs is positioned within the second heating zone and used to monitor a second temperature that is generated within the second heating zone near the upper surface of the heater.

In additional embodiments, the heater includes a bake plate formed from a ceramic material having a high thermal conductivity and low coefficient of thermal expansion. In other additional embodiments, the heater includes a bake plate formed from silicon nitride (Si₃N₄), SiAlON, aluminum nitride (AlN), aluminum oxide (Al₂O₃), or boron nitride (BN). In still further additional embodiments, the heater includes a bake plate, and the first resistive heating element, the second resistive heating element, and the plurality of RTDs are each formed from a metal material having a melting point, which is greater than a sintering temperature of the bake plate, and a thermal coefficient of expansion that is greater than or equal to that of a ceramic material used to form the bake plate.

In additional embodiments, the first resistive heating element, the second resistive heating element, and the plurality of RTDs are each formed from one or more of tungsten, molybdenum, a tungsten-molybdenum alloy, a nickel alloy, and a metal alloy.

In additional embodiments, each of the plurality of RTDs comprise a resistive grid of conductors that is configured to provide an electrical resistance between about 100 ohms and about 1000 ohms.

For one embodiment, a method is disclosed to independently monitor and control temperatures generated within multiple heating zones of a heater configured to thermally treat a substrate mounted on or above an upper surface of the heater. The method includes monitoring a first temperature generated within a first heating zone of the heater via a first resistance temperature detector (RTD) that is embedded within the heater and positioned within the first heating zone near the upper surface of the heater, monitoring a second temperature generated within a second heating zone of the heater via a second RTD that is embedded within the heater and positioned within the second heating zone near the upper surface of the heater, and independently controlling the first temperature and the second temperature based on output currents received from the first RTD and the second RTD, wherein the first RTD and the second RTD are embedded within the heater prior to sintering the heater, and wherein the first RTD and the second RTD are formed from a metal material having a melting point greater than a sintering temperature of the heater

In additional embodiments, the monitoring the first temperature and the monitoring the second temperature include receiving a first output current from the first RTD and a second output current from the second RTD, determining a first resistance from the first output current and a second resistance from the second output current, and using at least one temperature coefficient of resistance (TCR) curve to correlate the first resistance to the first temperature generated within the first heating zone of the heater and to correlate the second resistance to the second temperature generated within the second heating zone of the heater. In further embodiments, the independently controlling the first temperature and the second temperature includes using the first output current received from the first RTD to control an amount of current supplied to a first resistive heating element that is embedded within the heater to generate heat within a first heating zone of the heater and using the second output current received from the second RTD to control an amount of current supplied to a second resistive heating element that is embedded within the heater to generate heat within a second heating zone of the heater.

In another embodiment, a method of forming a heater configured to thermally treat a substrate mounted on or above an upper surface of the heater, wherein the heater comprises a bake plate and/or a susceptor cap coupled to the bake plate is provided. The method may comprise forming the bake plate from a ceramic material; providing at least one resistive heating element within the bake plate, wherein the at least one resistive heating element is embedded within the bake plate below the upper surface of the heater; providing a plurality of resistance temperature detectors (RTDs) within the bake plate or the susceptor cap, wherein the plurality of RTDs are embedded within the bake plate or the susceptor cap above the at least one resistive heating element and below the upper surface of the heater; and sintering the bake plate at a sintering temperature corresponding to the ceramic material.

In alternative embodiments of the method of forming a heater, the ceramic material comprises silicon nitride (Si₃N₄), SiAlON, aluminum nitride (AlN), aluminum oxide (Al₂O₃), or boron nitride (BN). In other alternatives, the plurality of RTDs are formed from a metal material having a melting point greater than the sintering temperature of the ceramic material. In still other alternatives, the plurality of RTDs are formed from one or more of tungsten, molybdenum, a tungsten-molybdenum alloy, a nickel alloy, and a metal alloy. In some alternatives the plurality of RTDs are formed by wire bonding of metal wires, sputtering, or printing. In some alternative embodiments, the providing a plurality of RTDs comprises (1) positioning a first RTD of the plurality of RTDs within a first heating zone of the heater, so that during operation of the heater, the first RTD is used to monitor a temperature that is generated within the first heating zone near the upper surface of the heater, and (2) positioning a second RTD of the plurality of RTDs within a second heating zone of the heater, so that during operation of the heater, the second RTD is used to monitor a temperature that is generated within the second heating zone near the upper surface of the heater.

Different or additional features, variations, and embodiments can also be implemented, and related systems and methods can be utilized as well.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 (Prior Art) is a side view of a bake module including a bake plate (or heater) used to thermally treat substrates.

FIG. 2 (Prior Art) is a side cross-sectional view of a bake plate (or heater) having a single resistive heating element and a single temperature sensor embedded therein, where the temperature sensor is a straight metal, type K thermocouple (TC) tube that is inserted within a hole formed and centered within the bake plate.

FIG. 3 (Prior Art) is a side cross-sectional view of another bake plate (or heater) having a plurality of resistive heating elements and a single temperature sensor embedded therein, where the temperature sensor is a straight metal, type K thermocouple (TC) tube that is inserted within a hole formed and centered within the bake plate.

FIG. 4 is a side cross-sectional view illustrating one embodiment of a heater comprising a bake plate having a plurality of resistive heating elements and a plurality of resistance temperature detectors (RTDs) embedded therein.

FIG. 5 is a side cross-sectional view illustrating another embodiment of a heater comprising a bake plate and a susceptor cap coupled to the bake plate, where a plurality of resistive heating elements is embedded within the bake plate and a plurality of RTDs is embedded within the susceptor cap.

FIG. 6 is a top view of one or more of the heaters shown in FIGS. 4 and 5 taken through line A-A, illustrating one embodiment of the RTDs shown and described therein.

FIG. 7 is a flowchart diagram illustrating one embodiment of a method that may be used to independently monitor and control temperatures generated within multiple heating zones of a heater that is configured to thermally treat a substrate mounted on or above an upper surface of the heater.

### DETAILED DESCRIPTION

Various embodiments of heaters used to thermally treat substrates (such as semiconductor wafers) are disclosed herein. More specifically, the present disclosure provides various embodiments of a heater having a plurality of resistance temperature detectors (RTDs) embedded therein. The present disclosure also contemplates various embodiments of bake modules including the heaters disclosed herein, as well as methods that use such heaters.

In the disclosed embodiments, the heater may include a bake plate and/or a susceptor cap coupled to the bake plate. In some embodiments, at least one heating element, such as a resistive heating element, may be embedded within the bake plate and configured to generate heat that is used to thermally treat (i.e., heat or bake) a substrate mounted on, or above, an upper surface of the heater. In some embodiments, a plurality of resistive heating elements may be embedded within the bake plate to create dual heating zones within the bake plate. For example, a first resistive heating element may be embedded within the bake plate to generate heat within a first heating zone of the bake plate, and a second resistive heating element may be embedded within the bake plate to generate heat within a second heating zone of the bake plate. It is recognized, however, that the least one resistive heating element disclosed herein is not restricted to any particular number, configuration or arrangement of heating elements.

In the disclosed embodiments, a plurality of RTDs are embedded within the bake plate, or within the susceptor cap coupled to the bake plate, to enable temperatures generated within each of the heating zone(s) to be accurately determined. In the disclosed embodiments, the plurality of RTDs are generally positioned above the at least one heating element (e.g., resistive heating element, or other heating element) near an upper surface of the heater for monitoring temperatures generated near the upper surface of the heater. In some embodiments, the plurality of RTDs may include a first RTD positioned within the first heating zone and a second RTD positioned within the second heating zone. In such embodiments, the first RTD may be used to measure a first temperature that is generated within the first heating zone near the upper surface of the heater, and the second RTD may be used to measure a second temperature that is generated within the second heating zone near the upper surface of the heater.

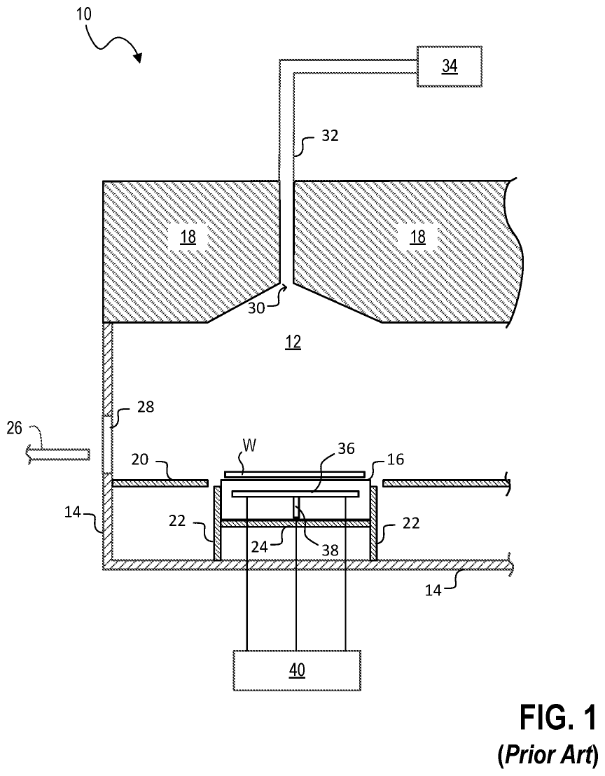

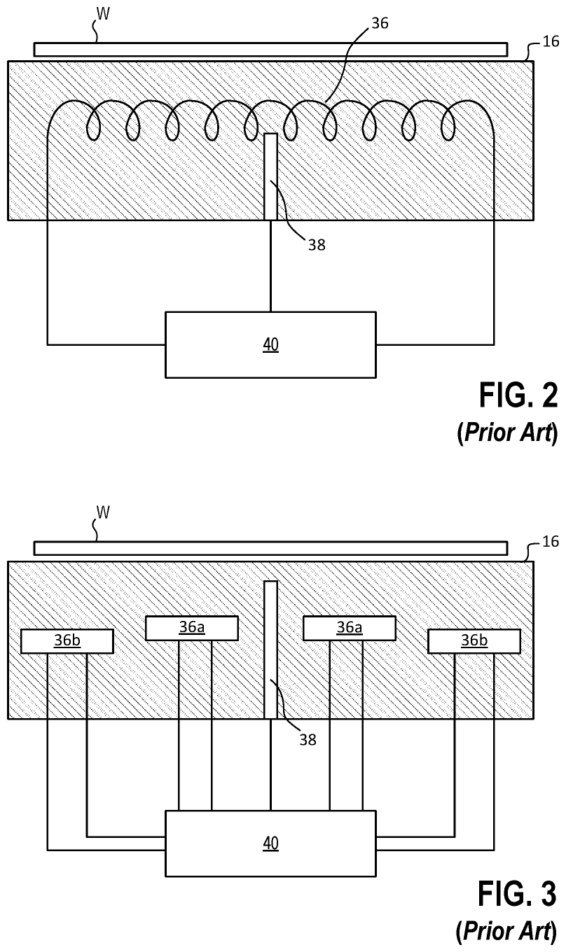

It is noted that the various embodiments of heaters disclosed herein may be included within a bake module that is configured to perform a bake process (such as a PAB, PEB, or PDB process) for a substrate. The substrate may be a semiconductor wafer (W) or another substrate for a microelectronic workpiece undergoing thermal treatment within the bake module. The bake module may be a stand-alone bake module or may be incorporated within a substrate processing system that includes various modules for processing substrates. FIG. 1 (Prior Art) illustrates one example of a bake module 10 in which the heaters disclosed herein may be utilized. It is recognized, however, that the heaters disclosed herein are not restricted to the bake module 10 shown in FIG. 1 (Prior Art) and may be utilized within alternatively configured bake modules, or within other processing modules used to thermally treat substrates.

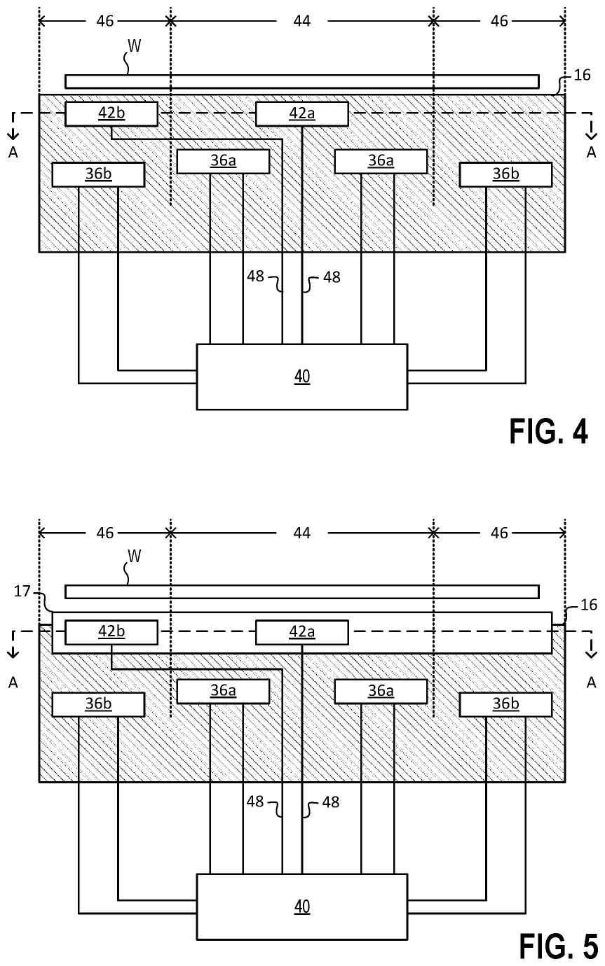

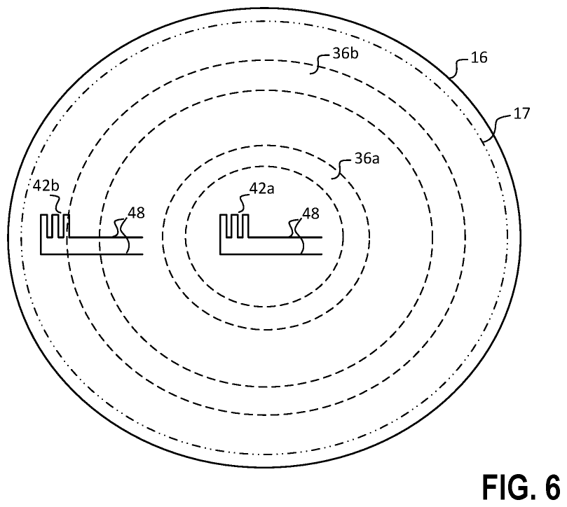

FIGS. 4-6 illustrate various embodiments of heaters including a bake plate 16 having at least one heating element 36, such as a resistive heating element, and a plurality of resistance temperature detectors (RTDs) 42. More specifically, FIG. 4 illustrates one embodiment of heater in which a plurality of resistive heating elements 36a/b and a plurality of RTDs 42a/b are embedded within the bake plate 16. FIG. 5 illustrates another embodiment of a heater in which a plurality of resistive heating elements 36a/b are embedded within the bake plate 16, and a plurality of RTDs 42a/b are embedded within a susceptor cap 17 coupled to the bake plate. FIG. 6 is a top view of the heaters shown in FIGS. 4 and 5 taken through line A-A, illustrating one embodiment of the RTDs shown therein.

In general, bake plate 16 may be formed from a ceramic material having a high thermal conductivity and low coefficient of thermal expansion, such as silicon nitride (Si₃N₄), SiAlON, aluminum nitride (AlN), aluminum oxide (Al₂O₃), boron nitride (BN), or a ceramic material having low electrical conductivity. Although not strictly limited to such, bake plate 16 may be formed from aluminum nitride, in at least one embodiment of the present disclosure. As noted above, aluminum nitride is commonly used to form bake plates used to thermally treat substrates, due to its high thermal conductivity (e.g., >130 W/mK), low coefficient of thermal expansion (e.g., 3-6 10⁻⁶/° C.), high maximum temperature (e.g., up to about 1700° C.) and excellent corrosion resistance. In some embodiments, bake plate 16 may be formed so as to include a substantially circular cross-sectional shape, as shown in FIG. 6. Alternatively, bake plate 16 may be formed having other cross-sectional shapes, including but not limited to, squares, rectangles, and/or other shapes or combinations of shapes. Other variations could also be implemented.

In general, at least one heating element 36, such as a resistive heating element, may be embedded within bake plate 16 to generate the heat used to thermally treat (i.e., heat or bake) a substrate mounted on, or above, an upper surface of the bake plate. In some embodiments, a plurality of resistive heating elements 36 may be embedded within bake plate 16 to generate heat within multiple, independently controlled heating zones. In the example embodiments shown in FIGS. 4-6, for example, a first resistive heating element 36a and a second resistive heating element 36b are embedded within bake plate 16 to create dual heating zones. As noted below, temperatures generated within the dual heating zones may be independently controlled, for example, by a controller 40 coupled to the resistive heating elements 36a/b. Although two resistive heating elements 36a/b are shown in FIGS. 4-6, one skilled in the art would recognize that a single heating element as well as three or more resistive heating elements may be embedded within the bake plate 16 shown in FIGS. 4-6 without departing from the scope of the present disclosure.

In general, the resistive heating element(s) 36 may be formed from a metal material having a high melting point and a thermal coefficient of expansion that is greater than or equal to that of the ceramic material used to form the bake plate 16. When bake plate 16 is formed from aluminum nitride (AlN), for example, the resistive heating element(s) 36 may be formed from tungsten, molybdenum or an alloy as well as from a nickel alloy or another a metal alloy having stability at high temperatures thereof to enable the resistive heating element(s) 36 to withstand high AlN sintering temperatures and to prevent microcracks from forming in the bake plate 16 over time. Other metal materials may be suitable for the resistive heating element(s) 36 when bake plate 16 is formed from other ceramic materials, such as silicon nitride (Si₃N₄) or SiAlON.

In some embodiments, the resistive heating element(s) 36 may be formed by wire bonding, sputtering, printing, and/or other processes or combination of processes. Further, the resistive heating element(s) 36 may be formed to have substantially any shape. In some embodiments, the resistive heating element(s) 36 may be formed to have a substantially circular cross-sectional shape, as shown in FIG. 6. Alternatively, the resistive heating element(s) 36 may be formed having other cross-sectional shapes, including but not limited to, squares, rectangles, and/or other shapes or combinations of shapes. Other variations could also be implemented.

In some embodiments, the resistive heating element(s) 36 may be positioned away from the upper surface of the bake plate 16 to prevent the resistive heating element(s) 36 from imprinting on a lower surface of the substrate. For example, the resistive heating element(s) 36 may be buried at a depth (D) between 2 millimeters (mm) and 50 mm (e.g., 2 mm≤D≤50 mm), or at a depth (D) of at least 5 mm (e.g., D≥5 mm), below the upper surface of the bake plate 16 to avoid imprinting on a lower surface of the substrate (or wafer, W).

In some embodiments, a controller 40 may be coupled and configured to control the temperature(s) generated within one or more heating zones of the bake plate 16 by controlling an amount of current supplied to the resistive heating element(s) 36. More specifically, a power source associated with controller 40 may be coupled to supply current to the resistive heating element(s) 36, and controller 40 may control the amount of current supplied by the power source to the resistive heating element(s) 36 to control the temperature(s) generated within the one or more heating zones by the resistive heating element(s) 36. As described in more detail below, controller 40 may be configured to independently control the amount of current supplied to each of the resistive heating element(s) 36 based on output currents received from a plurality of resistance temperature detectors (RTDs) 42. It is also noted that the power source does not have to be stopped for the measurements described herein to be made. Rather, measurements can be made while the power source is still active.

As noted above, conventional bake plates often use a straight metal, type K thermocouple (TC) tube to measure the temperature of the resistive heating element or the temperature of the bake plate. Because a straight metal, TC tube is relatively inflexible, it can only be used to measure temperature within the near vicinity of the thermocouple (e.g., within an inner heating zone of the bake plate), and cannot be used to measure temperature within other areas or zones of the bake plate (e.g., within an outer heating zone of the bake plate). Although temperatures within other areas or zones may be approximated (e.g., by applying an offset to the temperature measured by the thermocouple), the approximated temperature usually fails to properly control temperatures in the other areas or zones, often resulting in breakage of the bake plate.

Unlike conventional bake plates, the bake plate 16 shown in FIGS. 4-6 uses a plurality of resistance temperature detectors (RTDs) 42 for independently monitoring temperatures generated within multiple heating zones of the bake plate. In some embodiments, the plurality of RTDs 42 may be embedded within the bake plate 16, as shown in FIG. 4. In other embodiment, the plurality of RTDs 42 may be embedded within a susceptor cap 17 coupled to the bake plate 16, as shown in FIG. 5. Regardless, the plurality of RTDs 42 disclosed herein may be positioned above the resistive heating element(s) 36 near the upper surface of the bake plate 16 for monitoring temperatures generated near the upper surface of the bake plate. As such, the temperatures monitored by the plurality of RTDs 42 disclosed herein may closely approximate a temperature of the substrate mounted on, or above, the upper surface of the bake plate.

In some embodiments, the plurality of RTDs 42 may include a first RTD 42a and a second RTD 42b, as shown in FIGS. 4-6. In general, the first RTD 42a may be positioned within a first heating zone of the bake plate 16, and may be used to monitor a temperature that is generated within the first heating zone near the upper surface of the heater. Likewise, the second RTD 42b may be positioned within a second heating zone of the bake plate 16, and may be used to monitor a temperature that is generated within the second heating zone near the upper surface of the heater.

In the example embodiments shown in FIGS. 4-6, the first RTD 42a is positioned near a lateral center of the bake plate 16 for monitoring a temperature generated within an inner heating zone 44 of the bake plate, while the second RTD 42b is positioned near an outer edge of the bake plate for monitoring a temperature generated within an outer heating zone 46 of the bake plate. It is recognized, however, that bake plate 16 is not restricted to any particular number or arrangement of RTDs 42. In some embodiments, the two RTDs 42a/b shown in FIGS. 4-6 may be alternatively arranged within the bake plate 16 (or within the susceptor cap 17) to monitor temperatures within other areas or heating zones. In other embodiments, additional RTDs 42 are embedded within the bake plate 16 (or the susceptor cap 17) to monitor temperatures within three or more heating zones. Preferably, the RTDs embedded within the bake plate 16 are relatively high resistance (e.g., 100 ohms or greater) to improve accuracy, although other resistances can also be used while still taking advantage of the techniques described herein.

The plurality of RTDs 42 may generally be formed from a metal material having a high melting point and a thermal coefficient of expansion that is greater than or equal to that of the ceramic material used to form the bake plate 16. When bake plate 16 is formed from aluminum nitride (AlN), for example, the plurality of RTDs 42 may be formed from tungsten, molybdenum or an alloy thereof as well as from a nickel alloy or another a metal alloy having stability at high temperatures to enable the RTDs 42 to withstand high AlN sintering temperatures and to prevent microcracks from forming in the bake plate 16 over time. Other metal materials may be suitable for the plurality of RTDs 42 when bake plate 16 is formed from other ceramic materials, such as silicon nitride (Si₃N₄) or SiAlON.

In some embodiments, the plurality of RTDs 42 may be formed as a resistive grid of conductors 48, which may be used to monitor temperatures generated within two or more heating zones of the bake plate 16 (FIG. 4) or the susceptor cap 17 (FIG. 5). FIG. 6 illustrates one example of RTDs 42 formed as a resistive grid of conductors 48. Other configurations may also be suitable for implementing a resistive grid of conductors 48.

In some embodiments, the plurality of RTDs 42 are preferably implemented with metal wires, for example, by wire bonding of metal wires. Alternatively, the plurality of RTDs 42 may be formed by sputtering, printing, and/or other processes or combination of processes.

As shown in FIGS. 4-5, the conductors 48 of each RTD 42 may be routed through the bake plate 16 and coupled to the controller 40, so that the controller 40 can use the RTDs 42 to monitor temperatures generated within two or more heating zones of the bake plate 16 (FIG. 4) or the susceptor cap 17 (FIG. 5).

In some embodiments, controller 40 may supply an input current to the plurality of RTDs 42 and receive an output current from each RTD to monitor the temperatures generated within two or more heating zones within the bake plate 16 (FIG. 4) or the susceptor cap 17 (FIG. 5). The output current received from a given RTD is based on the electrical resistance of the RTD and the temperature generated within the bake plate 16 (or susceptor cap 17) in the near vicinity of the RTD. In some embodiments, the plurality of RTDs 42 may each be configured to provide an electrical resistance (R) of between about 100 ohms to about 1000 ohms (e.g., 100 ohms≤R≤1000 ohms). Since the electrical resistance of the RTDs 42 changes with temperature, the output currents received from the plurality of RTDs 42 may be used by the controller 40 to determine the temperatures generated in the near vicinity of the RTDs 42.

In some embodiments, controller 40 may use a Temperature Coefficient of Resistance (TCR) curve associated with the RTDs 42 to correlate the change in the electrical resistance of each of the RTDs 42 to temperature. For example, controller 40 may determine a resistance from an output current received from the first RTD 42a, and may use a TCR curve corresponding to the first RTD 42a to correlate a change in the resistance to the temperature generated within the inner heating zone 44 of the bake plate 16. Likewise, controller 40 may determine a resistance from an output current received from the second RTD 42b, and may use a TCR curve corresponding to the second RTD 42b to correlate a change in the resistance to the temperature generated within the outer heating zone 46 of the bake plate 16.

The temperature coefficient of resistance (TCR) curve defines the change in resistance of the RTD as a function of temperature, and may be calculated as follows:

$$TCR = \frac{R 2 - R 1}{R 1 ( T 2 - T 1 )} {10}^{- 6}$$

where R1 is the resistance (ohms) of the RTD at room temperature, R2 is the resistance (ohms) of the RTD at operating temperature, T1 is room temperature (in ° C.), and T2 is the temperature (in ° C.) generated in the vicinity of the RTD (e.g., the temperature generated within the inner heating zone 44 or the outer heating zone 46 of the bake plate 16). TCR is typically a fixed value (expressed in ppm/° C.), which is specified for a given RTD material. For example, when tungsten is used to fabricate the plurality of RTDs 42, a TCR of approximately 0.0045 ppm/° C. may be used in the equation above. In some cases, controller 40 may use more than one TCR curve or value to monitor the temperatures generated within the inner heating zone 44 and the outer heating zone 46 of the bake plate 16, if different materials are used to fabricate the plurality of RTDs 42.

In the embodiments shown in FIGS. 4-5, controller 40 is configured to independently control the temperatures generated within the inner heating zone 44 and the outer heating zone 46 of the bake plate 16 based on the output currents received from the plurality of RTDs 42. When a temperature generated within the inner heating zone 44 (or the outer heating zone 46) increases, the resistance of the first RTD 42a (or the second RTD 42b) increases, resulting in a decrease in the output current received from the first RTD 42a (or the second RTD 42b). In some embodiments, controller 40 may use the output currents received from the plurality of RTDs 42 to independently control the amount of current, which is supplied by the power source to the resistive heating elements 36a/b to generate heat within the inner heating zone 44 and the outer heating zone 46 of the bake plate 16. For example, controller 40 may use an output current received from the first RTD 42a to control the amount of current supplied to the resistive heating element 36a. In addition, controller 40 may use an output current received from the second RTD 42b to control the amount of current supplied to the resistive heating element 36b. By independently controlling the amount of current supplied to the resistive heating elements 36a/b, controller 40 more accurately controls the temperatures generated within the inner heating zone 44 and the output heating zone 46 of the bake plate 16.

Compared to conventional bake plates, the bake plate 16 shown in FIGS. 4-6 uses a plurality of RTDs 42 and a controller 40 to accurately monitor and independently control the temperatures generated within multiple heating zones of the bake plate. Unlike the straight metal, type K thermocouple tubes typically used within conventional bake plates, the RTDs 42 disclosed herein can be made from various high melting point metal materials (e.g., tungsten, molybdenum, nickel, metal alloys, etc.), which enable the RTDs to be sintered into the bake plate 16 or susceptor cap 17. Although FIGS. 4-6 demonstrate how two RTDs 42a/b may be used to monitor temperatures within the inner and outer heating zones 44/46 of the bake plate 16, the present disclosure is not strictly limited to the particular number or arrangement of RTDs shown and described therein. Instead, substantially any number of RTDs 42 can be used to monitor temperatures generated within substantially any area or zone of the bake plate 16 or susceptor cap 17 disclosed herein.

Controller 40 can be implemented in a wide variety of manners. In one example, the controller 40 may be a computer. In another example, the controller 40 may include one or more programmable integrated circuits that are programmed to provide the functionality described herein. For example, one or more processors (e.g., microprocessor, microcontroller, central processing unit, etc.), programmable logic devices (e.g., complex programmable logic device (CPLD)), field programmable gate array (FPGA), etc.), and/or other programmable integrated circuits can be programmed with software or other programming instructions to implement the functionality of the controller 40. It is further noted that the software or other programming instructions can be stored in one or more non-transitory computer-readable mediums (e.g., memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

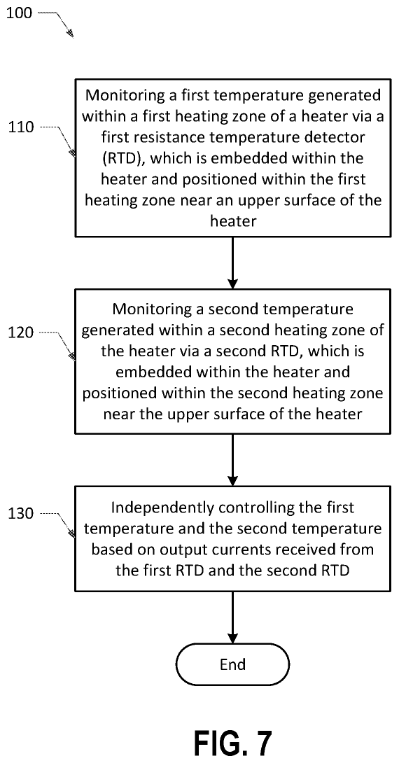

FIG. 7 illustrates one embodiment of a method 100 in accordance with the present disclosure. Method 100 may generally be used to independently monitor and control temperatures generated within multiple heating zones of a heater configured to thermally treat a substrate mounted on or above an upper surface of the heater. In some embodiments, method 100 may be performed by controller 40 to independently monitor and control temperatures generated within multiple heating zones of a heater, such as the various embodiments of heaters shown in FIGS. 4-6 and described above. It is recognized, however, that method 100 is not strictly limited to the example embodiments of heaters shown in FIGS. 4-6 and may be used to independently monitor and control temperatures generated within substantially any heater having multiple heating zones for thermally treating a substrate.

In general, method 100 includes monitoring a first temperature generated within a first heating zone of the heater via a first RTD (in step 110), monitoring a second temperature generated within a second heating zone of the heater via a second RTD (in step 120), and independently controlling the first temperature and the second temperature based on output currents received from the first RTD and the second RTD (in step 130). In the disclosed method, the first RTD is embedded within the heater and positioned within the first heating zone near the upper surface of the heater and the second RTD is embedded within the heater and positioned within the second heating zone near the upper surface of the heater.

In some embodiments, the monitoring of the first temperature (step 110) and the monitoring of the second temperature (step 120) may include receiving a first output current from the first RTD and a second output current from the second RTD, determining a first resistance from the first output current and a second resistance from the second output current, and using at least one temperature coefficient of resistance (TCR) curve to correlate the first resistance to the first temperature generated within the first heating zone of the heater, and correlate the second resistance to the second temperature generated within the second heating zone of the heater.

In some embodiments, the independently controlling of the first temperature and the second temperature (step 130) may include using the first output current received from the first RTD to control an amount of current supplied to a first resistive heating element that is embedded within the heater to generate heat within a first heating zone of the heater, and using the second output current received from the second RTD to control an amount of current supplied to a second resistive heating element that is embedded within the heater to generate heat within a second heating zone of the heater.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

In some embodiments, a substrate mounted on bake plate 16 and thermally treated within bake module 10 may be included within or form a part of a microelectronic workpiece. “Microelectronic workpiece” as used herein generically refers to the object being processed in accordance with the invention. The microelectronic workpiece may include any material portion or structure of a device, particularly a semiconductor or other electronics device, and may, for example, be a base substrate structure, such as a semiconductor substrate or a layer on or overlying a base substrate structure such as a thin film. Thus, workpiece is not intended to be limited to any particular base structure, underlying layer or overlying layer, patterned or unpatterned, but rather, is contemplated to include any such layer or base structure, and any combination of layers and/or base structures.

Various embodiments of heaters and bake modules for thermally treating a substrate or microelectronic workpiece are described herein. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the described heaters and bake modules will be apparent to those skilled in the art in view of this description. It will be recognized, therefore, that the described heaters and bake modules are not limited by these example arrangements. It is to be understood that the forms of the heaters and bake modules herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A bake module, comprising:
a heater configured to thermally treat a substrate mounted on or above an upper surface of the heater; and
a plurality of resistance temperature detectors (RTDs) embedded within the heater prior to sintering the heater and configured to sense temperatures for different zones of the heater.

2. The bake module of claim 1, wherein the heater comprises a bake plate and/or a susceptor cap coupled to the bake plate, and wherein at least one resistive heating element is embedded within the bake plate and configured to generate heat to thermally treat the substrate.

3. The bake module of claim 2, wherein the bake plate is formed from a ceramic material having a high thermal conductivity and a low coefficient of thermal expansion.

4. The bake module of claim 2, wherein the bake plate is formed from silicon nitride (Si₃N₄), SiAlON, aluminum nitride (AlN), aluminum oxide (Al₂O₃), or boron nitride (BN).

5. The bake module of claim 2, wherein the at least one resistive heating element and the plurality of RTDs are formed from a metal material having a high melting point and a thermal coefficient of expansion that is greater than or equal to that of a ceramic material used to form the bake plate.

6. The bake module of claim 2, wherein the plurality of RTDs are formed from a metal material having a melting point greater than a sintering temperature of the heater.

7. The bake module of claim 2, wherein the at least one resistive heating element and the plurality of RTDs are formed from one or more of tungsten, molybdenum, a tungsten-molybdenum alloy, a nickel alloy, and a metal alloy.

8. The bake module of claim 2, wherein the at least one resistive heating element comprises:
a first resistive heating element configured to generate heat within an inner heating zone of the heater; and
a second resistive heating element configured to generate heat within an outer heating zone of the heater.

9. The bake module of claim 2, wherein each of the plurality of RTDs is embedded within the bake plate, or within the susceptor cap coupled to the bake plate, and positioned above the at least one resistive heating element near the upper surface of the heater, and wherein:
a first RTD of the plurality of RTDs is further positioned near a lateral center of the bake plate and configured to provide a first output current corresponding to a first temperature that is generated within an inner heating zone of the bake plate near the upper surface of the heater; and
a second RTD of the plurality of RTDs is further positioned near an outer edge of the bake plate and configured to provide a second output current corresponding to a second temperature that is generated within an outer heating zone of the bake plate near the upper surface of the heater.

10. The bake module of claim 9, wherein the plurality of RTDs comprise a resistive grid of conductors, each of which is configured to provide an electrical resistance between about 100 ohms and about 1000 ohms.

11. The bake module of claim 9, further comprising a controller coupled to receive the first output current from the first RTD and the second output current from the second RTD, wherein the controller is configured to monitor the first temperature and the second temperature by:
determining a first resistance from the first output current;
determining a second resistance from the second output current; and
using at least one temperature coefficient of resistance (TCR) curve to:
correlate the first resistance to the first temperature generated within the inner heating zone of the bake plate; and
correlate the second resistance to the second temperature generated within the outer heating zone of the bake plate.

12. The bake module of claim 9, further comprising a controller coupled to receive the first output current from the first RTD and the second output current from the second RTD, wherein the controller is further configured to:
control the first temperature generated within the inner heating zone based on the first output current received from the first RTD; and
control the second temperature generated within the outer heating zone of the bake plate based on the second output current received from the second RTD, wherein the controller is configured to control the second temperature independently of the first temperature.

13. A heater configured to thermally treat a substrate mounted on or above an upper surface of the heater, wherein the heater comprises:
a first resistive heating element embedded within the heater to generate heat within a first heating zone of the heater;
a second resistive heating element embedded within the heater to generate heat within a second heating zone of the heater; and
a plurality of resistance temperature detectors (RTDs), each embedded within the heater prior to sintering the heater and positioned above the first resistive heating element and the second resistive heating element near the upper surface of the heater, wherein:
a first RTD of the plurality of RTDs is positioned within the first heating zone and used to monitor a first temperature that is generated within the first heating zone near the upper surface of the heater; and
a second RTD of the plurality of RTDs is positioned within the second heating zone and used to monitor a second temperature that is generated within the second heating zone near the upper surface of the heater.

14. The heater of claim 13, wherein the heater comprises a bake plate formed from a ceramic material having a high thermal conductivity and low coefficient of thermal expansion.

15. The heater of claim 13, wherein the heater comprises a bake plate formed from silicon nitride (Si₃N₄), SiAlON, aluminum nitride (AlN), aluminum oxide (Al₂O₃), or boron nitride (BN).

16. The heater of claim 13, wherein the heater comprises a bake plate, and wherein the first resistive heating element, the second resistive heating element, and the plurality of RTDs are each formed from a metal material having a melting point, which is greater than a sintering temperature of the bake plate, and a thermal coefficient of expansion that is greater than or equal to that of a ceramic material used to form the bake plate.

17. The heater of claim 13, wherein the first resistive heating element, the second resistive heating element, and the plurality of RTDs are each formed from one or more of tungsten, molybdenum, a tungsten-molybdenum alloy, a nickel alloy, and a metal alloy.

18. The heater of claim 13, wherein each of the plurality of RTDs comprise a resistive grid of conductors that is configured to provide an electrical resistance between about 100 ohms and about 1000 ohms.

19. A method to independently monitor and control temperatures generated within multiple heating zones of a heater configured to thermally treat a substrate mounted on or above an upper surface of the heater, the method comprising:
monitoring a first temperature generated within a first heating zone of the heater via a first resistance temperature detector (RTD) that is embedded within the heater and positioned within the first heating zone near the upper surface of the heater;
monitoring a second temperature generated within a second heating zone of the heater via a second RTD that is embedded within the heater and positioned within the second heating zone near the upper surface of the heater; and
independently controlling the first temperature and the second temperature based on output currents received from the first RTD and the second RTD;
wherein the first RTD and the second RTD are embedded within the heater prior to sintering the heater, and wherein the first RTD and the second RTD are formed from a metal material having a melting point greater than a sintering temperature of the heater.

20. The method of claim 19, wherein the monitoring the first temperature and the monitoring the second temperature comprise:
receiving a first output current from the first RTD and a second output current from the second RTD;
determining a first resistance from the first output current and a second resistance from the second output current; and
using at least one temperature coefficient of resistance (TCR) curve to:
correlate the first resistance to the first temperature generated within the first heating zone of the heater; and
correlate the second resistance to the second temperature generated within the second heating zone of the heater.
